(19) United States
(12) Patent Application Publication
(10) Pub. No.: US 2026/0317359 A1
(43) Pub. Date: Oct. 15, 2026

(54) CO-BASED ORGANIC COORDINATION NANOPARTICLE, PREPARATION METHOD THEREOF, PHOTORESIST COMPOSITION AND USE THEREOF

(71) Applicants: Beijing Vfortune New Energy Power Technology Development Co., Ltd., Beijing (CN); Tsinghua University, Beijing (CN)

(72) Inventors: Hong Xu, Beijing (CN); Xiangming He, Beijing (CN); Ziyu Hu, Beijing (CN)

(21) Appl. No.: 18/996,088

(22) PCT Filed: Jun. 14, 2024
(86) PCT No.: PCT/CN2024/099422

§ 371 Date: Jan. 17, 2025

(30) Foreign Application Priority Data
Jun. 27, 2023 (CN) 202310769734.5

(51) Int. Cl. C07F 15/06; B82Y 40/00; G03F 7/004; G03F 7/16; G03F 7/20

(52) U.S. Cl. CPC C07F 15/06; G03F 7/0042; G03F 7/162; G03F 7/2004; B82Y 40/00

(57) ABSTRACT

The present invention relates to a Co-based organic coordination nanoparticle, a preparation method therefor, a photoresist composition and the use thereof. The general formula of the Co-based organic coordination nanoparticle provided by the present invention is: CoₘRₙQₓM_{y}N_{z}, where Co is two ions, i.e. divalent Co and trivalent Co, R is selected from a benzoic acid group or a m-methylbenzoic acid group, Q can be selected from imidazole and a derivative thereof, M is carboxylic acid, and N is water of crystallization, the size of a Co-based organic coordination nanoparticle crystal being 1 nm-5 nm. The nanoparticles are prepared into a photoresist composition to be exposed and developed by electron beams or mid-ultraviolet, deep ultraviolet and extreme ultraviolet light, so that a pattern with high resolution, high sensitivity and low line roughness can be obtained. The Co-based organic coordination nanoparticle and the photoresist composition thereof which are provided by the present invention have good application potential in the field of EUV lithography.

### TECHNICAL FIELD

The invention relates to the technical field of photoresist, and in particular to a Co-based organic coordination nanoparticle and a preparation method therefor, a photoresist composition and use thereof.

### BACKGROUND

Photoresist refers to a corrosion-resistant thin film material whose solubility changes when exposed to Ultra-Violet light, electron beam, particle beam, Extreme Ultra-Violet (EUV) light or soft X-rays. With the continuous advancement of semiconductor technology and the development of Moore's Law, the semiconductor process continues to shrink, and higher requirements have been put forward for the reduction of processing feature size. In order to meet more advanced semiconductor processes and achieve smaller feature sizes, lithography technology is also continuously developing, from I-line, C-line, Deep Ultra-Violet (DUV), 193 nm, immersion 193 nm to fine processing means such as Extreme Ultra-Violet lithography, electron beam lithography. After the photoresist film is exposed and developed to form a lithographic pattern, it will be dry or wet etched. The part of the substrate material not covered by the film is directly etched, while the substrate surface covered by the film is protected by the photoresist film and is not etched. Etching resistance is a very important evaluation indicator of photoresist. Excellent etching resistance can ensure that the photoresist can protect the substrate surface from damage during the etching process, and effectively simplify the etching process, greatly improving the yield of the finished etching product.

Traditional photoresists have complex components, including a photoresist resin matrix, a photosensitive agent, a leveling agent, a stabilizer, a dispersant, a thickener and a solvent, etc. The manufacture process is tedious and requires extremely high control processes for the ratio and purity. Since traditional photoresists are mostly macromolecular polymers and contain many functional additives, their complex compositions lead to a wide distribution of photoresist sizes, with components of various sizes. Some size conformations can reach 10 nm~20 nm, making the size of photoresist patterns difficult to control and may cause many defects. In addition, for traditional photoresists, their application scope is greatly affected by the wavelength of the light source, and different photoresists are required to match different light sources. At present, metal oxide photoresist has become a research hotspot, and metal oxide photoresist has become a feasible choice for EUV or electron beam exposure of extremely fine patterns. Zn-based nano-organic ligand photoresist is a metal oxide organic ligand system studied by the applicant in the early stage, and its lithography effect has also been verified in practice. Co and Zn are close in position in the periodic table, and have certain similarities in properties, and have the potential to be used as photoresists, but there is no report on Co-based nano-organic ligand photoresist. The present invention conducts in-depth research around this material system and synthesizes a Co-based nano-organic photoresist composition with good lithography effect.

### SUMMARY

### Technical Problem

Aiming at the problem that the edge roughness of the pattern obtained by conventional photoresist lithography is large and the pattern resolution is low, the present invention proposes a new Co-based organic coordination nanoparticle and a preparation method therefor, a photoresist composition containing the same and use thereof.

### Technical Solutions

### [Prepared Metal Organic Nanoparticle]

The present invention provides a Co-based organic coordination nanoparticle, having a general formula of CoₘRₙQₓM_{y}N_{z}, wherein Co is two ions of divalent Co ion and trivalent Co ion; each of m, n and x is greater than 0, and y and z are greater than or equal to 0 respectively;

R is selected from

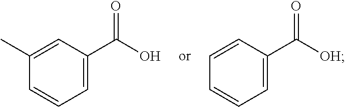

Q is selected from imidazole and its derivatives;

M is a carboxylic acid;

N is crystallization water;
the size of the Co-based organic coordination nanoparticle crystal is 1 nm to 5 nm.

Furthermore, the Co-based organic coordination nanoparticle may have the following structure:

Co₁₂(C₆H₅COO)₁₂(CH₃C₂N₂H₃)₁₂(CH₃COO)₁₈(H₂O)₆; or

Co₂(C₇H₇COO)₄(CH₃C₂N₂H₃)₂.

### [Method for Preparing Metal-Organic Coordination Nanoparticle]

Nanoparticle Co₂(C₇H₇COO)₄(CH₃C₂N₂H₃)₂ is prepared by the following method:
adding m-methylbenzoic acid or benzoic acid and cobalt acetate to a flask respectively;
adding an organic solvent to dissolve m-methylbenzoic acid or benzoic acid and cobalt acetate; and then
adding 1-methylimidazole, stirring continuously under a certain temperature condition, and rotating and evaporating under a certain steam pressure to obtain a product.

Further, the molar ratio of m-methylbenzoic acid or benzoic acid to cobalt acetate is in the range of 1:2~2:1, and the molar ratio of m-methylbenzoic acid or benzoic acid, cobalt acetate, and 1-methylimidazole is in the range of 1:1:(1~3).

The organic solvent is any one or more selected from ethyl acetate, butyl acetate, propylene glycol monoethyl ether acetate, propylene glycol methyl ether acetate, 1-ethoxy-2-propanol, tetrahydrofuran, methanol, ethanol and propanol.

The stirring temperature is controlled at 25~125° C., preferably 30~100° C., more preferably 30~80° C.; the rotary evaporation pressure range is controlled at 70~140 mBar, preferably 70~120 mBar, more preferably 80~100 mBar; at the same time, the rotary evaporation temperature is controlled at 30~45° C., preferably 30~40° C.

### [Metal-Organic Coordination Nanoparticle Photoresist]

The present invention also provides a photoresist composition, comprising the above-mentioned Co-based organic coordination nanoparticle.

Further, the above-mentioned photoresist composition also includes a photoinitiator and an organic dispersing solvent, the photoinitiator preferably makes up 0.5 wt %-10 wt % of the composition, and the nanoparticle preferably makes up 3 wt %-20 wt % of the composition.

Further, the photoinitiator is any one or more selected from N-hydroxynaphthalimide trifluoromethanesulfonic acid, 1,4-aminonaphthalenesulfonic acid, 2-amino-5,7-naphthalene disulfonic acid, tert-butylphenyl iodonium perfluorooctanesulfonic acid, triphenylsulfonium perfluorobutanesulfonic acid, triphenylsulfonium perfluorobutyl and triphenylsulfonium trifluorosulfonic acid.

Further, the organic dispersing solvent is any one or more selected from ethyl acetate, butyl acetate, propylene glycol monoethyl ether acetate, propylene glycol methyl ether acetate, 1-ethoxy-2-propanol, methanol, ethanol and propanol. The solvent is preferably ethyl acetate.

### [Method for Patterning Metal-Organic Coordination Nanoparticle in Photoresist]

The present invention also provides a method for forming a lithographic pattern, using the above-mentioned photoresist composition, dripping the photoresist composition onto a substrate by spin coating, heating the substrate on a hot stage, then exposing the substrate under electron beam, Mid-Ultra-Violet, Deep Ultra-Violet, or Extreme Ultra-Violet, and developing the substrate with a developing agent.

Further, the spin coating speed is 1500~2500 rpm; the heating temperature of the hot stage is controlled at 50~80° C., and the heating period is controlled within 40~120 s.

Further, the exposure dose is 50 mJ/cm²~500 mJ/cm², and the preferred exposure dose is 150 mJ/cm²~300 mJ/cm².

Further, the development period may be selected within 3~10 s, preferably 3 s, 5 s or 7 s.

Further, the developing agent is any one or any mixture of more selected from decalin, tetralin, indene, indane, quinoline, I-methylnaphthalene, toluene, o-xylene, m-xylene, ethyl acetate, butyl acetate, ethanol, n-propanol, isopropanol, n-butanol, n-hexane and cyclohexane, and the developing temperature is room temperature or 20° C.~50° C.

The thickness of the pre-film layer after removing the organic dispersing solvent may be from 10 nm to 100 nm. Specifically, the thickness of the pre-film layer may be 10 nm~20 nm, 20 nm~30 nm, 30 nm~40 nm, 40 nm~50 nm, 50 nm~60 nm, 60 nm~70 nm, 70 nm~80 nm, 80 nm~90 nm, 90 nm~100 nm.

The substrate is selected from a silicon sheet. Other substrates that are insoluble in the developing agent can also be selected according to actual needs.

Furthermore, the use of the above nanoparticles is in the field of photoresists, especially photoresists for electron beam, Mid-Ultra-Violet, Deep Ultra-Violet, and Extreme Ultra-Violet. Regarding the mask, a transmission mask is adopted for the Deep Ultra-Violet and longer wavelength light sources, a reflection mask is adopted for the Extreme Ultra-Violet, and the electron beam is used for exposure according to the pattern set by the software.

### Beneficial Effects

Compared with the prior art, the technical solution of the present invention has the following advantages:

The Co-based organic coordination nanoparticle obtained by the present invention has a special structure. Under illumination conditions, it can interact with a photoinitiator, change the polarity of the material, and agglomerate, resulting in changes in the solubility of the Co-based organic coordination nanoparticle before and after light exposure. Due to these characteristics, the Co-based organic coordination nanoparticle can be used as a photoresist component to make the solubility of the photosensitive part and the light-shielding part of the photoresist in the developing agent different. The photosensitive part agglomerates and the solubility thereof decreases in the developing agent, while the light-shielding part does not agglomerate and dissolves in the developing agent, so that the non-exposed area can be removed after development to obtain a pattern of the desired shape. Using the Co-based organic coordination nanoparticle of the present invention as a photoresist component can achieve more excellent lithography performance such as high resolution, high sensitivity, and low line roughness.

### BRIEF DESCRIPTION OF THE DRAWINGS

FIG. 1 is a DLS particle size test diagram of the purple viscous liquids prepared in Example 1 and Example 14 of the present invention, wherein the left curve is the test result of Example 1, and the right curve is the test result of Example 14;

FIG. 2A and FIG. 2B are chemical structure diagrams of the crystals prepared in Example 1 and Example 14 of the present invention, respectively;

FIG. 3 is an infrared spectrum test diagram of the crystals prepared in Example 1 and Example 14 of the present invention;

FIGS. 4-15 are the exposure patterns corresponding to Examples 2-13 of the present invention respectively;

FIGS. 16-27 are the exposure patterns corresponding to Examples 15-26 of the present invention respectively;

FIG. 28 is the exposure pattern of Example 27 of the present invention.

### DETAILED DESCRIPTION OF THE PREFERRED EMBODIMENTS

In order to facilitate the understanding of the present invention, the present invention will be described more completely below with reference to the relevant drawings. The preferred embodiments of the present invention are shown in the drawings. However, the present invention can be implemented in many different forms and is not limited to the embodiments described herein. On the contrary, the purpose of providing these embodiments is to make the understanding of the disclosure of the present invention more thorough and comprehensive.

Unless otherwise defined, all technical and scientific terms used herein have the same meaning as those generally understood by the skilled person in the technical field of the present invention. The terms used in the specification of the present invention herein are only for the purpose of describing specific embodiments and are not intended to limit the present invention.

The present invention provides a Co-based organic coordination nanoparticle, the general formula of which is CoₘRₙQₓM_{y}N_{z};
wherein, Co is two ions of divalent Co ion and trivalent Co ion:
R may be selected from

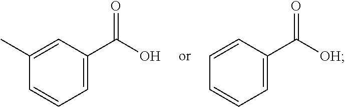

Q may be selected from imidazole and its derivatives;
M is a carboxylic acid; N is crystallization water.

Further, the size of the Co-based organic coordination nanoparticle crystal is from 1 nm to 5 nm.

Each of in, n and x is greater than 0, v and z are greater than or equal to 0. Further, 2≤m≤12, 4≤n≤12, 2≤x≤12, 0≤y≤18, 0≤z≤6.

Further, the Co-based organic coordination nanoparticle can be the following structure:

Co₁₂(C₆H₅COO)₁₂(CH₃C₂N₂H₃)₁₂(CH₃COO)₁₈(H₂O)₆; or

Co₂(C₇H₇COO)₄(CH₃C₂N₂H₃)₂.

The Co-based organic coordination nanoparticle obtained by the present invention has a special structure, and under illumination conditions, can interact with a photoinitiator, change the polarity of the material, and agglomerate, hereby causing the solubility of the Co-based organic coordination nanoparticle to change before and after illumination. Due to these characteristics, the Co-based organic coordination nanoparticle can be used as a photoresist component to make the solubility of the photosensitive part and the light-shielding part of the photoresist in the developing agent different. The photosensitive part agglomerates and the solubility thereof is reduced in the developing agent, while the light-shielding part does not agglomerate and dissolves in the developing agent, so that the non-exposed area can be removed after development to obtain a pattern of a desired shape. The Co-based organic coordination nanoparticle of the present invention can be used as a photoresist component to achieve more excellent lithography performances such as high resolution, high sensitivity, and low line roughness.

In particular, nanoparticle Co₂(C₇H₇COO)₄(CH₃C₂N₂H₃)₂ is prepared by the following method:
adding m-methylbenzoic acid or benzoic acid and cobalt acetate into a flask respectively, adding an organic solvent to dissolve m-methylbenzoic acid or benzoic acid and cobalt acetate, then adding 1-methylimidazole thereto, stirring the solution continuously under a certain temperature condition, and rotating and evaporating to obtain the product under a certain steam pressure.

Further, the molar ratio of m-methylbenzoic acid or benzoic acid to cobalt acetate is in the range of 1:2~2:1, and the molar ratio of m-methylbenzoic acid or benzoic acid, cobalt acetate, and 1-methylimidazole is in the range of 1:1:(1~3).

The organic solvent is any one or more selected from ethyl acetate, butyl acetate, propylene glycol monoethyl ether acetate, propylene glycol methyl ether acetate, 1-ethoxy-2-propanol, tetrahydrofuran, methanol, ethanol and propanol.

The stirring temperature is controlled at 25~125° C., preferably 30~100° C., more preferably 30~80° C.; the rotary evaporation pressure range is controlled at 70~140mBar, preferably 70~120 mBar, more preferably 80~100 mBar; at the same time, the rotary evaporation temperature is controlled at 30~45° C., preferably 30~40° C.

The present invention also provides a photoresist composition, comprising the above-mentioned Co-based organic coordination nanoparticle. Further, the above-mentioned photoresist composition also comprises a photoinitiator and an organic dispersing solvent, the photoinitiator preferably makes up 0.5 wt %-10 wt % of the composition, and the nanoparticle preferably makes up 3 wt %-20 wt % of the composition.

Further, the photoinitiator is any one or more selected from N-hydroxynaphthalimide trifluoromethanesulfonic acid, 1,4-aminonaphthalenesulfonic acid, 2-amino-5,7-naphthalene disulfonic acid, tert-butylphenyl iodonium perfluorooctanesulfonic acid, triphenylsulfonium perfluorobutanesulfonic acid, triphenylsulfonium perfluorobutyl and triphenylsulfonium trifluorosulfonic acid.

Further, the organic dispersing solvent is any one or more selected from ethyl acetate, butyl acetate, propylene glycol monoethyl ether acetate, propylene glycol methyl ether acetate, 1-ethoxy-2-propanol, methanol, ethanol and propanol. The solvent is preferably ethyl acetate.

The present invention also provides a method for forming a lithographic pattern, using the above-mentioned photoresist composition, dripping the photoresist composition onto a substrate by spin coating, heating the substrate on a hot table, then exposing the substrate with electron beam or Mid-Ultra-Violet, Deep Ultra-Violet, or Extreme Ultra-Violet, and developing the substrate with a developing agent.

The spin coating speed is further controlled at 1500-2500 rpm; the heating temperature of the hot stage is controlled at 50-80° C., and the heating period is controlled within 40-120 s.

Further, the exposure dose is 50 mJ/cm²~500 mJ/cm², and the preferred exposure dose is 150 mJ/cm²~300 mJ/cm².

Further, the development time may be selected within 3-10 s, preferably 3 s, 5 s and 7 s.

Further, the developing agent is any one or any mixture of more selected from decalin, tetralin, indene, indane, quinoline, 1-methylnaphthalene, toluene, o-xylene, m-xylene, ethyl acetate, butyl acetate, ethanol, n-propanol, isopropanol, n-butanol, n-hexane and cyclohexane, and the development temperature is room temperature or 20° C.~50°.

The thickness of the pre-film layer after removing the organic dispersing solvent may be 10 nm~100 nm. Specifically, the thickness of the pre-film layer may be 10 nm~20 nm, 20 nm~30 nm, 30 nm~40 nm, 40 nm~50 nm, 50 nm~60 nm, 60 nm~70 nm, 70 nm~80 nm, 80 nm~90 nm, or 90 nm~100 nm.

The substrate is selected from a silicon sheet. Other substrates that are insoluble in the developing agent can also be selected according to actual needs.

Further, the use of the above-mentioned nanoparticles is in the field of photoresists, especially photoresists for electron beam, Mid-Ultra-Violet, Deep Ultra-Violet, and Extreme Ultra-Violet. Regarding the mask, a transmission mask is adopted for the Deep Ultra-Violet and longer wavelength light sources, a reflection mask is adopted for the Extreme Ultra-Violet, and the electron beam is used for exposure according to the pattern set by the software.

### Example 1

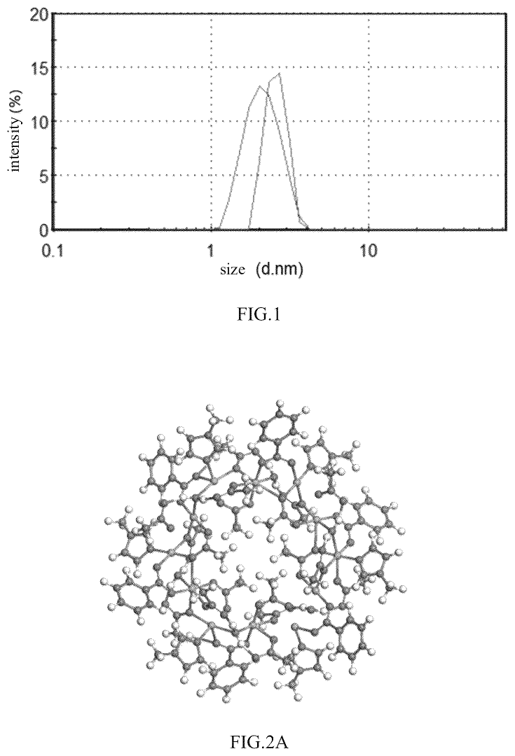

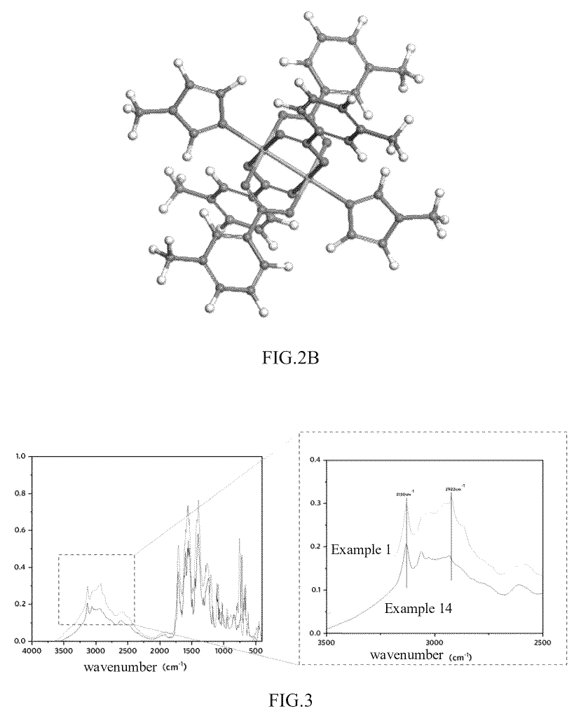

4.88 g (40 mmol) benzoic acid and 4.98 g (20 mmol) cobalt acetate were added to a 100 mL flask respectively, and 45 mL tetrahydrofuran was added. 1.67~2.30 g (20~28 mmol) 1-methylimidazole was added thereto, and stirred and heated at 25~125° C. for 24 hours. The solution was rotated and evaporated at 70~140 mBar and 30~45° C. for 20~40 minutes to obtain a purple viscous liquid. The DLS particle size test was performed on the obtained product. The results are shown in the left curve in FIG. 1. It can be seen that the prepared system is a nanoparticle (average particle size 3.1 nm). Furthermore, crystals could be obtained by leaving the liquid at a low temperature, and was subjected to an infrared spectrum test, and the test results were shown in FIG. 3. It can be seen that there is an absorption peak at 3130 cm⁻¹, which is the absorption peak of the aromatic ring after bonding, because the infrared absorption peak of free benzoic acid is between 3000 and 3100 cm⁻¹, corresponding to the stretching vibration of the unsaturated benzene ring ═C—H of the benzoic acid group, that is, a slight shift from the position of the benzoic acid absorption peak occurs in the synthesized Co-based organic coordination structure material, which indicates that the benzoic acid group is bonded to the molecular structure of the metal organic compound. Combined with the results of nuclear magnetic resonance analysis, the molecular structure Co₁₂(C₆H₅OO)₁₂(CH₃C₂N₂H₃)₁₂(CH₃COO)₁₈(H₂O)₆ is analyzed out, as shown in FIG. 2A. It is a multi-core complex with benzoic acid, N-methylimidazole and acetate as ligands, containing 12 Co rings, and except for N-methylimidazole, the other ligands are connected around the Co ring in the form of bridges. It can be seen that the substance prepared by the method of this example is metal organic coordinated nanoparticle.

### Examples 2-4

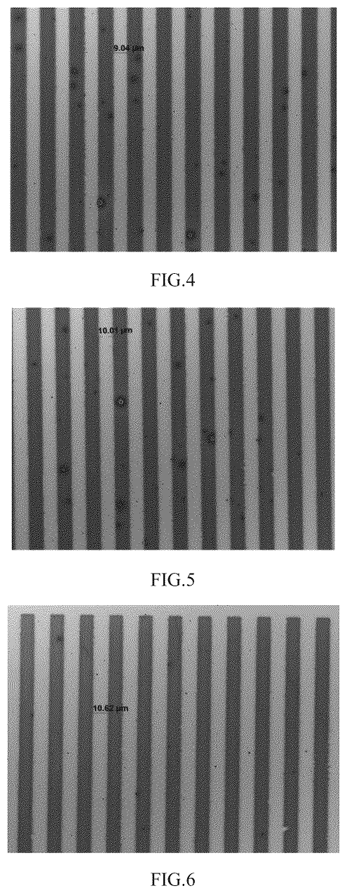

0.5 wt % PAG-1 (N-hydroxynaphthalimide trifluoromethanesulfonate) was added to the solution prepared in Example 1 (5.0 wt %), the solvent was propylene glycol monoethyl ether acetate. The resulted mixture was spin-coated on the silicon sheet at a speed of 2000 rpm, and then heated on a hot plate at 50° C. for 1 minute. The above photoresist film was exposed under a 254 nm ultraviolet mercury lamp with a dose of 150 mJ/cm², and mesitylene was used as a developing agent. The development was performed for 3 s, 5 s and 7 s, respectively, to obtain line exposure patterns with half-pitch of 9.04 μm, 10.01 μm and 10.62 μm, as shown in FIGS. 4, 5 and 6, respectively.

### Examples 5-7

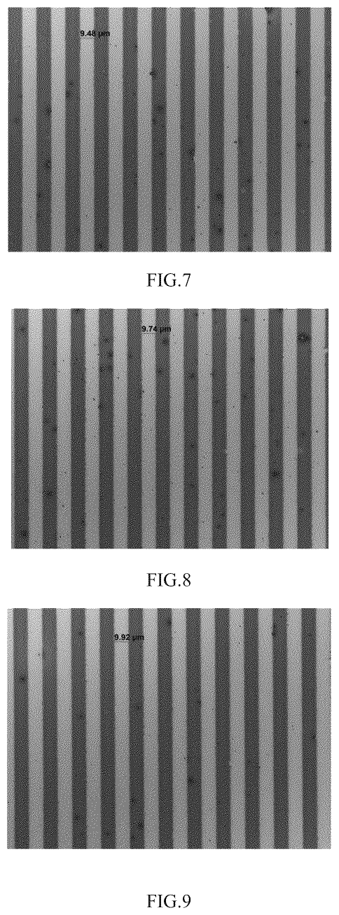

0.5 wt % PAG-1 (N-hydroxynaphthalimide trifluoromethanesulfonate) was added to the solution prepared in Example 1 (5.0 wt %), the solvent was propylene glycol monoethyl ether acetate. The resulted mixture was spin-coated on the silicon sheet at a speed of 2000 rpm, and then heated on a hot plate at 60° C. for 1 minute. The above photoresist film was exposed under a 254 nm ultraviolet mercury lamp with a dose of 150 mJ/cm², and mesitylene was used as a developing agent. The development was performed for 3 s, 5 s and 7 s, respectively, to obtain line exposure patterns with half-pitch of 9.48 μm, 9.74 μm and 9.92 μm, as shown in FIGS. 7, 8 and 9, respectively.

### Examples 8-10

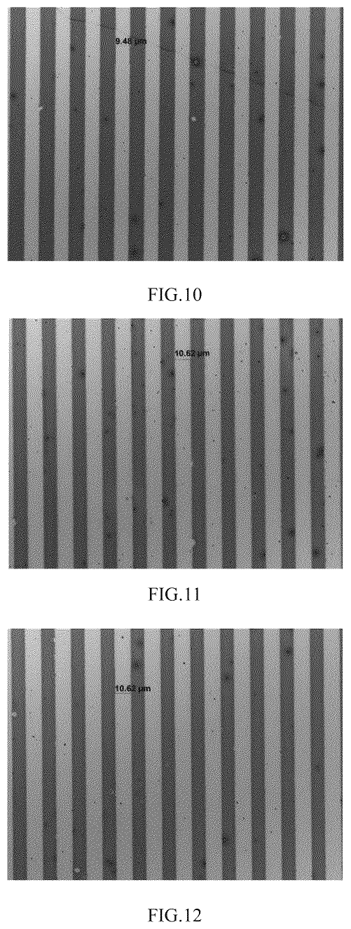

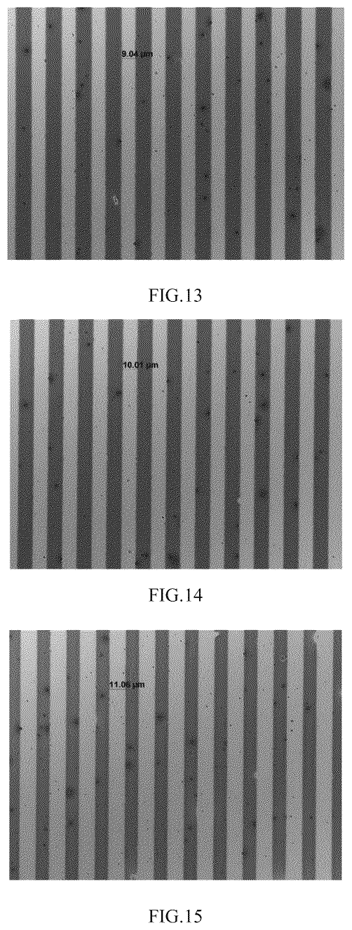

0.5 wt % PAG-1 (N-hydroxynaphthalimide trifluoromethanesulfonate) was added to the solution prepared in Example 1 (5.0 wt %), the solvent was propylene glycol monoethyl ether acetate. The resulted mixture was spin-coated on the silicon sheet at a speed of 2000 rpm, and then heated on a hot plate at 70° C. for I minute. The above photoresist film was exposed under a 254 nm ultraviolet mercury lamp with a dose of 150 mJ/cm², and mesitylene was used as a developing agent. The development was performed for 3 s, 5 s and 7 s, respectively, to obtain line exposure patterns with half-pitch of 9.48 μm, 10.62 μm and 10.62 μm, as shown in FIGS. 10, 11 and 12, respectively.

### Examples 11-13

0.5 wt % PAG-1 (N-hydroxynaphthalimide trifluoromethanesulfonate) was added to the solution prepared in Example 1 (5.0 wt %), the solvent was propylene glycol monoethyl ether acetate. The resulted mixture was spin-coated on the silicon sheet at a speed of 2000 rpm, and then heated on a hot plate at 80° C. for 1 minute. The above photoresist film was exposed under a 254 nm ultraviolet mercury lamp with a dose of 150 mJ/cm², and mesitylene was used as a developing agent. The development was performed for 3 s, 5 s and 7 s, respectively, to obtain line exposure patterns with half-pitch of 9.04 μm, 10.01 μm and 11.06 μm, as shown in FIGS. 13, 14 and 15, respectively.

### Example 14

5.44 g (40 mmol) of m-methylbenzoic acid and 4.98 g (20 mmol) of cobalt acetate were added to a 100 mL flask, and 45 ml, of tetrahydrofuran was added. 1.67~2.30 g (20~28 mmol) of 1-methylimidazole was added. The resulted mixture was stirred and heated at 25~125° C. for 24 hours. The product was rotated and evaporated at 70~140 mBar and 30~45° C. for 20~40 minutes to obtain a purple viscous liquid. The product was subjected to the DLS particle size test. The results are shown in the right curve of FIG. 1. It can be seen that the prepared system is a nanoparticle (average particle size 4.3 nm). Further, the liquid was left to stand at low temperatures to obtain a crystal, and was subjected to an infrared spectrum test to obtain the test results as shown in FIG. 3. It can be seen that there are absorption peaks at 2922 cm⁻¹ and 3130 cm⁻¹ respectively, and the free i-methyl benzoic acid has an additional C—H peak of alkyl below 3000 cm⁻¹, besides a stretching vibration absorption peak at 3000~3100 cm⁻¹ corresponding to the absorption peak of the unsaturated ═C—H of the benzoic acid group in the benzene ring, and the infrared absorption spectrum of the product prepared by the present example also has corresponding absorption peaks near these two positions, and slight shifts have occurred, which shows that the m-methyl benzoic acid group is bonded to the molecular structure of the metal organic compound. The material prepared by the method of the present example is a metal organic coordinated nanoparticle. The molecular structure is shown in FIG. 2B, Co₂(C₇H₇COO)₄(CH₃C₂N₂H₃)₂.

### Examples 15-17

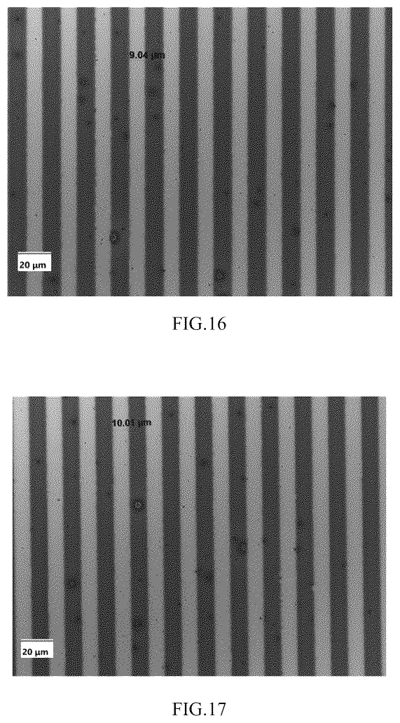

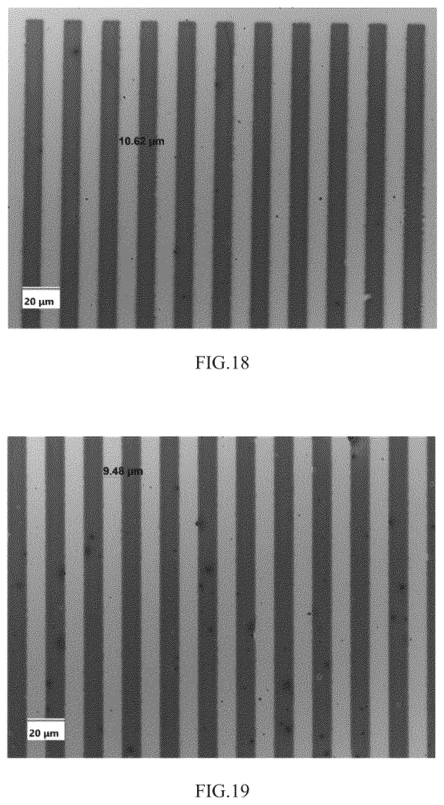

0.5 wt % PAG-1 (N-hydroxynaphthalimide trifluoromethanesulfonate) was added to the solution prepared in Example 14 (5.0 wt %), the solvent was propylene glycol monoethyl ether acetate. The resulted mixture was spin-coated on the silicon sheet at a speed of 2000 rpm, and then heated on a hot plate at 50° C. for 1 minute. The above photoresist film was exposed under a 254 nm ultraviolet mercury lamp with a dose of 150 mJ/cm², and mesitylene was used as a developing agent. The development was performed for 3 s, 5 s and 7 s respectively, to obtain line exposure patterns with half-pitch of 1 μm, as shown in FIGS. 16, 17 and 18, respectively.

### Examples 18-20

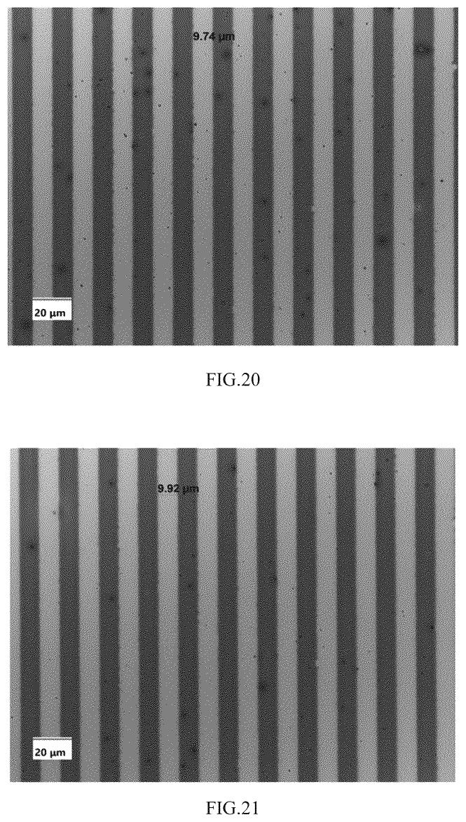

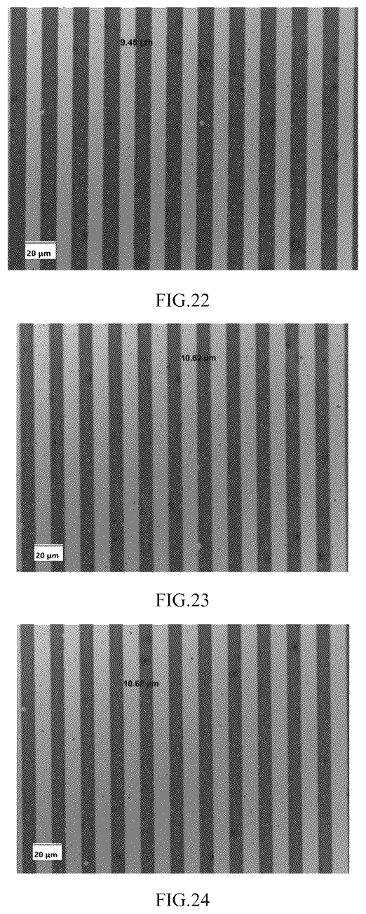

0.5 wt % PAG-1 (N-hydroxynaphthalimide trifluoromethanesulfonate) was added to the solution prepared in Example 14 (5.0 wt %), the solvent was propylene glycol monoethyl ether acetate. The resulted mixture was spin-coated on the silicon sheet at a speed of 2000 rpm, and then heated on a hot plate at 60° C. for 1 minute. The above photoresist film was exposed under a 254 nm ultraviolet mercury lamp with a dose of 150 mJ/cm², and mesitylene was used as a developing agent. The development was performed for 3 s, 5 s and 7 s respectively, to obtained line exposure patterns with half-pitch of 1 μm as shown in FIGS. 19, 20 and 21, respectively.

### Examples 21-23

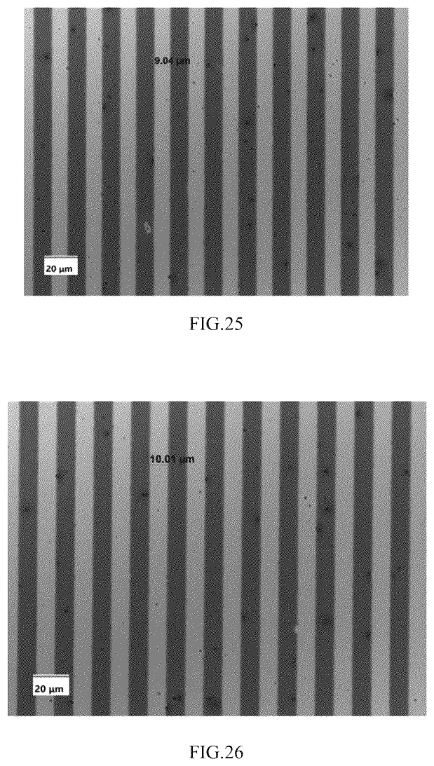

0.5 wt % PAG-1 (N-hydroxynaphthalimide trifluoroethanesulfonate) was added to the solution prepared in Example 14 (5.0 wt %), the solvent was propylene glycol monoethyl ether acetate. The resulted mixture was spin-coated on the silicon sheet at a speed of 2000 rpm, and then heated on a hot plate at 70° C. for 1 minute. The above photoresist film was exposed under a 254 nm ultraviolet mercury lamp with a dose of 150 mJ/cm², and mesitylene was used as a developing agent. The development was performed for 3 s, 5 s and 7 s respectively, to obtain line exposure patterns with half-pitch of 1 μm, as shown in FIGS. 22, 23 and 24, respectively.

### Examples 24-26

0.5 wt % PAG-1 (N-hydroxynaphthalimide trifluoromethanesulfonate) was added to the solution prepared in Example 14 (5.0 wt %), the solvent was propylene glycol monoethyl ether acetate. The resulted mixture was spin-coated on the silicon sheet at a speed of 2000 rpm, and then heated on a hot plate at 80° C. for 1 minute. The above photoresist film was exposed under a 254 nm ultraviolet mercury lamp with a dose of 150 mJ/cm² and mesitylene was used as a developing agent. The development was performed for 3 s, 5 s and 7 s respectively, to obtain line exposure patterns with half-pitch of 1 μm, as shown in FIGS. 25, 26 and 27, respectively.

### Example 27

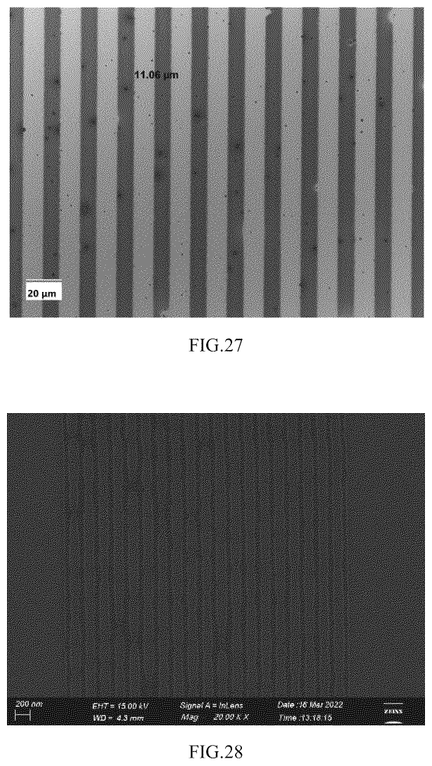

10 wt % PAG-1 (N-hydroxynaphthalimide trifluoromethanesulfonate) was added to the solution prepared in Example 14 (3.5 wt %), the solvent was propylene glycol monoethyl ether acetate. The resulted mixture was spin-coated on the silicon sheet at a speed of 2000 rpm, and then heated on a hot plate at 60° C. for 1 minute. EBL exposure was performed with a dose of 850 μC/cm² and a beam intensity of 1.0~3.0 A, mesitylene was used as the developing agent, the development time was 9 s, to obtain lines with half-pitch of 100 nm, as shown in FIG. 28.

In summary, the present invention obtains a variety of effective nanoparticles and corresponding compositions, whose structures were verified, and have good lithography performance under Mid-Ultra-Violet and electron beam lithography (EBL) conditions, thus achieving high resolution, high sensitivity, low line roughness and other more excellent lithography performance.

1. A Co-based organic coordination nanoparticle, having a general composition formula of CoₘRₙQₓM_{y}N_{z}, wherein Co is two ions of divalent Co ion and trivalent Co ion, each of m, n and x is greater than 0, and y and z are greater than or equal to 0 respectively;
R is selected from 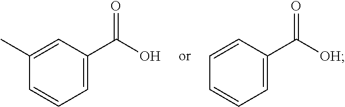
Q is selected from imidazole and its derivatives;
M is a carboxylic acid;
N is crystallization water; and
the size of the Co-based organic coordination nanoparticle crystal is nm to 5 nm.

2. The Co-based organic coordination nanoparticle according to claim 1, wherein the structure of the nanoparticle is Co₁₂(C₆H₅COO)₁₂(CH₃C₂N₂H₃)₁₂(CH₃COO)₁₈(H₂O)₆ or Co₂(C₇H₇COO)₄(CH₃C₂N₂H₃)₂.

3. The method for preparing the Co-based organic coordination nanoparticle according to claim 1, specifically comprising the following steps:
adding m-methylbenzoic acid or benzoic acid and cobalt acetate to a flask respectively;
adding an organic solvent to dissolve m-methylbenzoic acid or benzoic acid and cobalt acetate; and then
adding 1-methylimidazole to the solution, stirring the solution continuously under a certain temperature condition, and rotating and evaporating the solution under a certain steam pressure to obtain a product.

4. The method for preparing a Co-based organic coordination nanoparticle according to claim 3, wherein the molar ratio of m-rmethylbenzoic acid or benzoic acid to cobalt acetate is in the range of 0.5~2, and the molar ratio of m-methylbenzoic acid or benzoic acid:cobalt acetate:1-methylimidazole is in the range of 1:1:(1~3).

5. The method for preparing a Co-based organic coordination nanoparticle according to claim 3, wherein the organic solvent is any one or more selected from ethyl acetate, butyl acetate, propylene glycol monoethyl ether acetate, propylene glycol methyl ether acetate, 1-ethoxy-2-propanol, tetrahydrofuran, methanol, ethanol and propanol.

6. The method for preparing a Co-based organic coordination nanoparticle according to claim 3, wherein the stirring temperature is controlled at 25~125° C., the rotary evaporation pressure range is controlled within 70~140mBar, and the rotary evaporation temperature is controlled at 30~45° C.

7. A photoresist composition, comprising the Co-based organic coordination nanoparticle according to claim 1, a photoinitiator and an organic dispersing solvent, wherein the photoinitiator makes up 0.5 wt %~10 wt % of the composition, and the nanoparticle makes up 3 wt %~20 wt % of the composition.

8. The photoresist composition according to claim 7, wherein the photoinitiator is any one or more selected from N-hydroxynaphthalimide trifluoromethanesulfonic acid, 1,4-aminonaphthalenesulfonic acid, 2-amino-5,7-naphthalene disulfonic acid, tert-butylphenyl iodonium perfluorooctanesulfonic acid, triphenylsulfonium perfluorobutanesulfonic acid, triphenylsulfonium perfluorobutyl and triphenylsulfonium trifluorosulfonic acid.

9. The photoresist composition according to claim 7, wherein the organic dispersing solvent is any one or more selected from ethyl acetate, butyl acetate, propylene glycol monoethyl ether acetate, propylene glycol methyl ether acetate, 1-ethoxy-2-propanol, methanol, ethanol and propanol.

10. A method for forming a lithographic pattern, comprising:
using the photoresist composition according to claim 7;
dripping the photoresist composition onto a substrate by spin coating;
heating the substrate on a hot stage; then
exposing the substrate under electron beam, Mid-Ultra-Violet, Deep Ultra-Violet, or Extreme Ultra-Violet;
developing the substrate with a developing agent; and
wherein the spin coating speed is 1500~2500 rpm; the heating temperature of the hot stage is controlled at 50~80° C., the heating period is controlled within 40~120 s, the exposure dose is 50 mJ/cm²~500 mJ/cm², and the development period is 3~10 s.

11. The method for forming a lithographic pattern according to claim 10, wherein the developing agent is any one or any mixture of more selected from decalin, tetralin, indene, indane, quinoline, 1-methylnaphthalene, toluene, o-xylene, m-xylene, ethyl acetate, butyl acetate, ethanol, n-propanol, isopropanol, n-butanol, n-hexane and cyclohexane, and the development temperature is room temperature or 20° C.~50° C.

12. The method for forming a lithographic pattern according to claim 10, wherein the thickness of the pre-film layer after removing the organic dispersing solvent is 10 nm~100 nm.

13. Use of the Co-based organic coordination nanoparticle according to claim 1 mainly in photoresists for electron beam, Mid-Ultra-Violet, Deep Ultra-Violet or Extreme Ultra-Violet.
